(19) United States
(12) Patent Application Publication
(10) Pub. No.: US 2002/0187435 A1
(43) Pub. Date: Dec. 12, 2002

(54) Method of illuminating a layer of a material, in particular of photosensitive resin

(75) Inventors: Serdar Manakli, Grenoble (FR); Yorick Trouillet, Grenoble (FR)

Correspondence Address: FLEIT, KAIN, GIBBONS,, GUTMAN & BONGINI, P.L., ONE BOCA COMMERCE CENTER, 551 NORTHWEST 77TH STREET, SUITE 111, BOCA RATON, FL, 33487, US

(73) Assignee: STMICROELECTRONICS S.A., MONTROUGE (FR)

(21) Appl. No.: 10/114,428

(22) Filed: Apr. 2, 2002

(30) Foreign Application Priority Data
Apr. 3, 2001 (FR) 0104514

(51) Int. Cl. G03F 7/20

(52) U.S. Cl. 430/322; 430/394; 430/396

(57) ABSTRACT

A method of illuminating a layer of a material, in particular a photosensitive resin, using a light source, in order to expose an area of that material to a useful dose of light for subsequent etching of that material in that area, consisting in effecting a first exposure through a pattern of a first mask made up of a central hole and peripheral holes with a first dose of light less than said useful dose, and a second exposure through a pattern of a second mask made up of a single hole with a second dose of light such that the cumulative total of said first dose induced through the central hole of the first mask and the second dose induced through the single hole of said second mask produces at least said useful dose over said area.

### CROSS REFERENCE TO RELATED APPLICATIONS

This application is based upon and claims priority from prior French Patent Application No. 0104514, filed Apr. 3, 2001, the disclosure of which is hereby incorporated by reference in its entirety.

### BACKGROUND OF THE INVENTION

1. Field of the Invention

The present invention relates to photolithography as used in particular in the field of integrated circuit fabrication.

2. Description of Related Art

In the semiconductors industry, a constant aim is to reduce the size of the basic components of integrated circuits fabricated in large numbers on wafers in produce to obtain integrated circuits of with improved performance and a reduced size.

When fabricating integrated circuits on wafers, it is routine practice to use photolithography steps which consist of exposing a layer of photosensitive resin to light so that three-dimensional patterns appear in the layer of resin after etching the exposed parts. This applies in particular in the case of forming contact holes for electrical interconnections between the various layers of the integrated circuits.

Where the photolithography step is concerned, an improvement in performance is obtained by reducing the resolution of the exposed patterns, which conventionally entails reducing the wavelength of the exposure light.

In the case of forming a hole in a layer of photosensitive resin, it is routine practice to effect a single exposure or illumination via a mask having a single hole through which passes the dose of light necessary for subsequent etching of the resin layer. It has also been proposed to effect a single exposure through a mask having a central hole and peripheral holes, the dose of light necessary for subsequent etching of the layer of resin passing only through the central hole.

Also, multidirectional illumination of the mask and quadripolar or annular illumination of the mask using a central obstacle placed between the light source and the mask are known in the art.

Although these prior art techniques for forming a hole in a layer of photosensitive resin are useful, they are not without their shortcomings. One shortcoming is the inability to form holes with very small dimension. It has been observed that the techniques described above have limitations, especially when forming isolated holes in a layer of photosensitive resin having dimensions of reducing size. Accordingly, a need exist to overcome these short comings and to provide a method to provide holes in a layer of resin where the holes have a reduced size.

### SUMMARY OF THE INVENTION

Briefly, in accordance with the present invention disclosed is a method of illuminating a layer of a material, in particular of a photosensitive resin, using a light source, in order to expose an area of that material to a useful dose of light for subsequent etching of that material. The method improves and enhances the performance of the operation of exposing the material in the area, in particular for the subsequent formation of holes with very small dimensions in the resin layer. In accordance with the invention, the above method consists in: placing between the light source and the layer of the material a first mask having a pattern made up of a central hole and holes placed at the periphery of the central hole; effecting a first exposure through the pattern of the first mask with a first dose of light less than the useful dose; placing between the light source and the layer of the material a second mask having a pattern made up of a single hole, with the second mask in a position such that its single hole corresponds to the central hole of the first mask; and effecting a second exposure through the pattern of the second mask with a second dose of light such that the cumulative total of the first dose induced through the central hole of the first mask and the second dose induced through the single hole of the second mask produces at least the useful dose over the area.

According to the invention, the method can advantageously consist in effecting the second exposure with a second dose of light less than the useful dose.

According to the invention, the single hole of the second mask preferably has an area greater than that of the central hole of the first mask.

According to the invention, the method can advantageously consist in effecting the first exposure with quadripolar or annular illumination.

According to the invention, the method can advantageously consist in effecting the second exposure with quadripolar or annular illumination.

According to the invention, the first and second patterns can advantageously be formed on a single mask or on two separate masks.

### BRIEF DESCRIPTION OF THE DRAWINGS

The subject matter which is regarded as the invention is particularly pointed out and distinctly claimed in the claims at the conclusion of the specification. The foregoing and other features, and advantages of the invention will be apparent from the following detailed description taken in conjunction with the accompanying drawings.

FIG. 1 is an optical diagram of photolithography apparatus, accordance with the present invention.

FIG. 2a is a first mask used in the method in accordance with the present invention.

FIG. 2b is a curve of the distribution of the quantity of light reaching the material to be exposed through the FIG. 2a mask along a median axis II-II in FIG. 2a, in accordance with the present invention.

FIG. 3a is a second mask used in the method according to the present invention.

FIG. 3b is a curve of the distribution of the quantity of light reaching the material to be exposed through the FIG. 3a mask, in accordance with the present invention.

FIG. 4 represents a curve of the sum of the quantities of light reaching the material to be exposed, in accordance with the present invention.

FIG. 5 is a top view of the material after exposure, in accordance with the present invention.

### DETAILED DESCRIPTION OF AN EMBODIMENT

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in the plural and vice versa with no loss of generality.

In the drawing like numerals refer to like parts through several views.

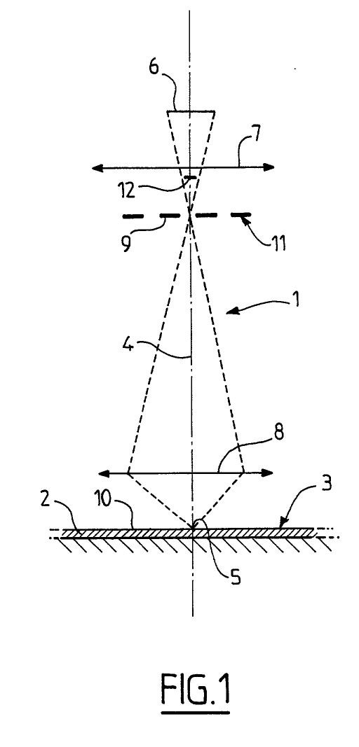

FIG. 1 shows exposure or photolithography apparatus 1 for exposing to light a photosensitive resin layer 2 of a wafer 3 of integrated circuits in the process of fabrication, in accordance with the present invention.

The apparatus 1 includes, in succession, along an optical axis 4 extending perpendicularly to the wafer 3 and corresponding to the axis of a hole 5 to be formed in the resin layer 2, a light source 6, a condenser 7 and an entry pupil 8, such that there is one focal plane 9 between the condenser 7 and the entry pupil 8 and one focal plane 10 on the photosensitive resin layer 2.

The apparatus 1 includes a support 11 in the focal plane 9 that can receive a mask, and an obstacle 12 is placed on the optical axis 4 between the condenser 6 and the focal plane 9 to produce a quadripolar or annular light beam or illumination.

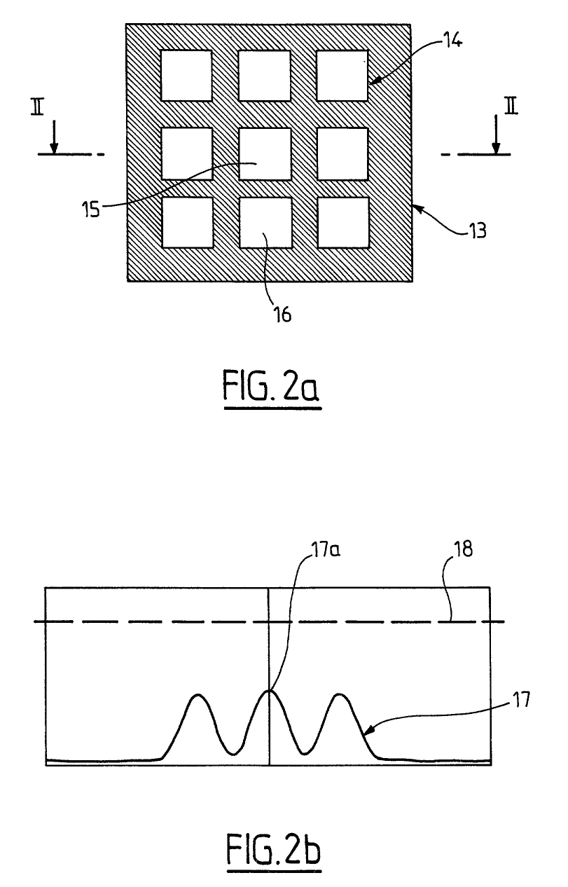

FIG. 2a shows a first mask or reticule 13 that comprises a pattern 14 consisting of a square central hole 15 and eight square peripheral holes 16 arranged around and at a distance from the central hole 14 to constitute a matrix of nine regularly distributed holes.

Having installed the mask 13 in the mask support 11 of the apparatus 1 in a position such that the axis of the central hole 15 is on the optical axis 4, the photosensitive resin layer 2 is illuminated through the pattern 14.

FIG. 2b shows that the doses of light passing through the central hole 15 and the peripheral hole 16 of the pattern 14 of the mask 13 take the form of nine bells 17 and that the light source 6 is activated so that the doses 17 have maximum values 17a that are less than a useful dose level 18.

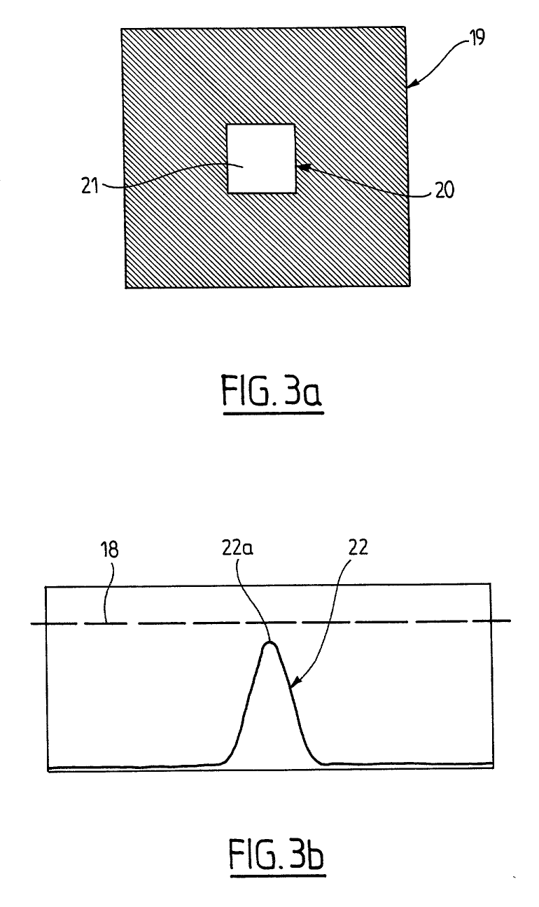

FIG. 3a represents a second mask 19 which has a pattern 20 consisting of a single square hole 21 whose area is greater than that of the central hole 15 of the pattern 14 of the first mask 13.

Having placed the second mask 19 on the support 11 of the apparatus 1 in a position such that the axis of the single hole 21 is on the optical axis 4, the photosensitive resin layer 2 of the wafer 3 is illuminated.

FIG. 3b shows that the dose of light passing through the single hole 21 of the second mask 19 takes the form of a bell 22 and that the light source 6 is activated so that the dose 22 has a maximum value 22a that is less than the level of the useful dose 18.

It follows from the foregoing that the photosensitive resin layer 2 of the wafer is illuminated through the pattern 14 of the first mask 13 and then through the pattern 20 of the second mask 19, leading to the cumulative total of a first dose of light and a second dose of light.

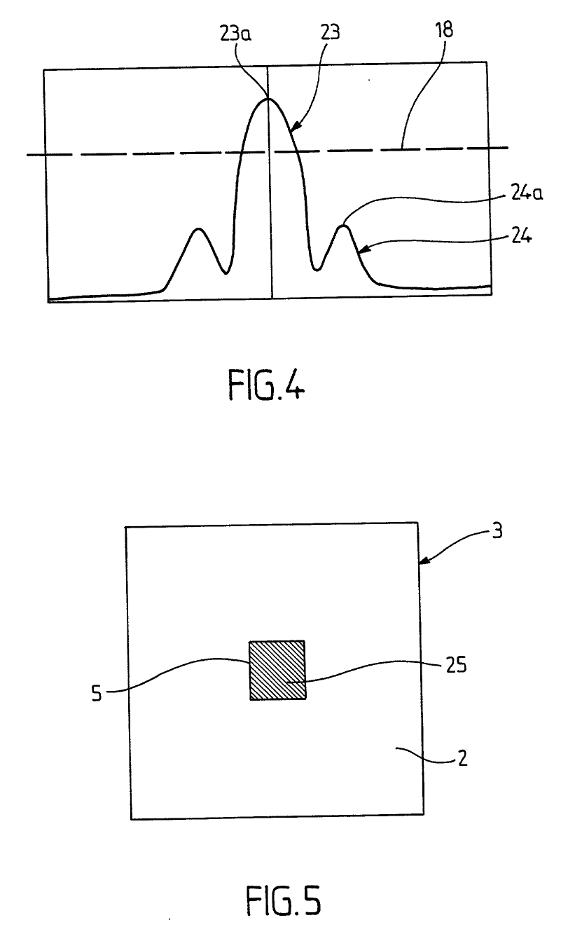

FIG. 4 shows that the cumulative total dose 23 of light reaching the photosensitive resin layer 2 of the wafer 3 and resulting from successive illumination through the central hole 15 of the pattern 14 of the first mask 13 and the single hole 21 of the pattern 20 of the second mask 19 takes the form of a bell 23 and that the aforementioned maximum values 17a and 22a of the doses of light 17 and 22 are chosen so that the maximum level 23a of the cumulative total dose 23 is above the useful dose level 18. Moreover, the doses 24 corresponding to the peripheral holes 16 of the mask 13 have a respective maximum level 24a that remains below the useful dose level 18.

It follows from the foregoing that, as shown in FIG. 5, the photosensitive resin layer 2 of the wafer 3 is exposed over an area 25 that corresponds to the cross section of the cumulative dose 23 at the level of the useful dose 18.

Accordingly, subsequent etching of the photosensitive resin layer 2 of the wafer 3 produces the required hole 5 in the exposed area 25.

The present invention is not limited to the example described hereinabove. In particular, the patterns 14 and 20 could be formed in two places on a single mask. Also, the two exposures described could be interchanged.

Although a specific embodiment of the invention has been disclosed, it will be understood by those having skill in the art that changes can be made to this specific embodiment without departing from the spirit and scope of the invention. The scope of the invention is not to be restricted, therefore, to the specific embodiment, and it is intended that the appended claims cover any and all such applications, modifications, and embodiments within the scope of the present invention.

What is claimed is:

1. A method of illuminating a layer of a material, the method comprising:
placing a first mask in between a light source and a layer of a material, the first mask including a pattern with a central hole and a plurality of peripheral holes placed around the central hole;
exposing a selected area of the layer of material through the pattern of the first mask with a first dose of light, wherein the first dose is less than a useful dose of light required for subsequent etching of the selected area;
placing a second mask between the light source and the layer of the material, the second mask including a pattern made up of a single hole, and the second mask in a position such that the single hole is aligned to an identical optical axis as the central hole of the first mask; and
exposing the selected area through the pattern of the second mask with a second dose of light;
wherein a cumulative total of the first dose of light combined with the second dose of light produces at least the useful dose over the selected area of the layer of material.

2. The method according to claim 1, wherein the exposing the selected area through a pattern of a second mask includes exposing the selected area through a pattern of a second mask with a second dose of light that is less than the useful dose.

3. The method according to claim 1, wherein the placing a second mask includes placing a second mask with a single hole that has an area greater than an area of the central hole of the first mask.

4. The method according to claim 2, wherein the placing a second mask includes placing a second mask with a single hole that has an area greater than an area of the central hole of the first mask.

5. The method according to claim 1, wherein exposing a selected area through the pattern of the first mask with a first dose of light includes exposing a selected area through the pattern of the first mask with a first dose of light using one of a quadripolar illumination or a annular illumination.

6. The method according to claim 2, wherein exposing a selected area through the pattern of the first mask with a first dose of light includes exposing a selected area through the pattern of the first mask with a first dose of light using one of a quadripolar illumination or a annular illumination.

7. The method according to claim 3, wherein exposing a selected area through the pattern of the first mask with a first dose of light includes exposing a selected area through the pattern of the first mask with a first dose of light using one of a quadripolar illumination or a annular illumination.

8. The method according to claim 4, wherein exposing a selected area through the pattern of the first mask with a first dose of light includes exposing a selected area through the pattern of the first mask with a first dose of light using one of a quadripolar illumination or an annular illumination.

9. The method according to claim 1, wherein exposing a selected area through the pattern of the second mask with a second dose of light includes exposing with a second dose of light using one of a quadripolar illumination or an annular illumination.

10. The method according to claim 2, wherein exposing the selected area through the pattern of the second mask with a second dose of light includes exposing with a second dose of light using one of a quadripolar illumination or an annular illumination.

11. The method according to claim 3, wherein exposing the selected area through the pattern of the second mask with a second dose of light includes exposing with a second dose of light using one of a quadripolar illumination or an annular illumination.

12. The method according to claim 7, wherein exposing the selected area through the pattern of the second mask with a second dose of light includes exposing with a second dose of light using one of a quadripolar illumination or an annular illumination.

13. The method according to claim 8, wherein exposing the selected area through the pattern of the second mask with a second dose of light includes exposing with a second dose of light using one of a quadripolar illumination or an annular illumination.

14. The method according to claim 1, wherein the first and second patterns are formed on a single mask or on two separate masks.

15. The method according to claim 2, wherein the first and second patterns are formed on a single mask or on two separate masks.

16. The method according to claim 3, wherein the first and second patterns are formed on a single mask or on two separate masks.

17. The method according to claim 4, wherein the first and second patterns are formed on a single mask or on two separate masks.

18. The method according to claim 7, wherein the first and second patterns are formed on a single mask or on two separate masks.

19. The method according to claim 8, wherein the first and second patterns are formed on a single mask or on two separate masks.

20. The method according to claim 12, wherein the first and second patterns are formed on a single mask or on two separate masks.

21. The method according to claim 12, wherein the first and second patterns are formed on a single mask or on two separate masks.

22. A method of illuminating a layer of material for subsequent etching in a photolithography system, the method comprising:
passing a first dose of light from a light source through a first mask onto a selected area of a layer of material, wherein the first dose is less than a useful dose of light required for subsequent etching of the selected area and wherein the first mask includes a pattern with a central holes and a plurality of peripheral holes placed around the central hole;
passing a second dose of light from the light source through a second mask onto the selected area of the layer of material, wherein the second mask includes a pattern made up of a single hole, and the second mask in a position such that the single hole is aligned to an identical optical axis as the central hole fo the first mask so that a cumulative total of the first dose of light combined with the second does of light produces at least the useful dose over the selected area of the layer of material.
